(19) United States
(12) Patent Application Publication
(10) Pub. No.: US 2015/0014661 A1
(43) Pub. Date: Jan. 15, 2015

(54) ORGANIC LIGHT EMITTING DISPLAY DEVICE AND METHOD OF MANUFACTURING AN ORGANIC LIGHT EMITTING DISPLAY DEVICE

(71) Applicant: Samsung Display Co., Ltd., Yongin-city (KR)

(72) Inventors: Sung-Joong JOO, Yongin-si (KR); You-Min Cha, Asan-si (KR)

(21) Appl. No.: 14/325,099

(22) Filed: Jul. 7, 2014

(30) Foreign Application Priority Data
Jul. 9, 2013 (KR) 10-2013-0080188

(51) Int. Cl. H01L 27/32; H01L 51/52; H01L 51/56

(52) U.S. Cl. CPC H01L 27/3211; H01L 51/56; H01L 51/5234; H01L 51/5228
USPC 257/40; 438/35

(57) ABSTRACT

A organic light emitting display device including a first substrate on which red, green, and blue pixels are formed, the red, green, and blue pixels display including a plurality of first electrodes disposed corresponding to the red, green, and blue pixels, respectively, a plurality of organic light emitting structures emitting white light disposed above the first electrodes, respectively, a plurality of second electrodes respectively disposed on the organic light emitting structures, and a plurality of secondary transparent electrodes disposed between the first electrodes and the organic light emitting structures. The secondary transparent electrodes have different thicknesses from each other by a printing process such that red light, green light, and blue light are respectively emitted by the red, green, and blue pixels when the white light causes resonance to occur between the first electrodes and the second electrodes.

### CROSS-REFERENCE TO RELATED APPLICATION

This application claims priority from and the benefit of Korean Patent Application No. 10-2013-0080188, filed on Jul. 9, 2013, which is hereby incorporated by reference for all purposes as if fully set forth herein.

### BACKGROUND

1. Field

Exemplary embodiments of the present invention relate to organic light emitting display devices and methods of manufacturing the same. More particularly, exemplary embodiments of the present invention relate to organic light emitting display devices using a micro-cavity effect, and methods of manufacturing organic light emitting display devices using a micro-cavity effect.

2. Discussion of the Background

An organic light emitting display (OLED) device may display desired information such as images, letters, and/or characters using light generated by the combination of holes provided from an anode, and electrons provided from a cathode, in an organic layer thereof. The OLED device has several advantages over other types of displays, such as wide viewing angle, high response time, reduced thickness, and low power consumption, so that the OLED device may be widely employed in various electrical and electronic apparatuses. Recently, the OLED device has been rapidly developed as one of the most promising display devices.

In general, a white organic light emitting display (White-OLED) device using a micro-cavity effect realizes full-color display by adjusting the distance of optical resonance by controlling the respective thicknesses of resonance layers included in a plurality of pixels. The distance of optical resonance may be determined according to thickness of a transparent electrode, or a first electrode in each pixel. A desired thickness of the transparent electrode may be obtained by repeated developing and etching processes. However, because the developing and etching processes are repeatedly performed to obtain the desired thickness of the transparent electrode, the costs of production may increase, and process reproducibility may decrease. Further, by the repeated processes, unwanted particles may be produced, which results in the defects in the OLED device.

The above information disclosed in this Background section is only for enhancement of understanding of the background of the invention and, therefore, it may contain information that does not form the prior art that is already known in this country to a person of ordinary skill in the art.

### SUMMARY

Exemplary embodiments of the present invention provide an organic light emitting display device using a printing process to form a secondary transparent electrode.

Exemplary embodiments of the present invention also provide a method of manufacturing an organic light emitting display device using a printing process to form a secondary transparent electrode.

Additional features of the invention will be set forth in part in the description which follows and, in part will be apparent from the description, or may be learned by practice of the invention.

An exemplary embodiment of the present invention discloses an organic light emitting display device including a first substrate on which red, green, and blue pixels are formed, the red, green and blue pixels including first electrodes disposed respectively corresponding to the red, green, and blue pixels, organic light emitting structures disposed above the first electrodes respectively corresponding to the red, green, and blue pixels, the organic light emitting structures emitting white light, second electrodes respectively disposed on the organic light emitting structures, and secondary transparent electrodes disposed between the first electrodes and the organic light emitting structures, respectively. The secondary transparent electrodes may be formed to have different thicknesses from each other by a printing process such that red light, green light, and blue light are respectively emitted by the red, green, and blue pixels when the white light causes resonance to occur between the first electrodes and the second electrodes.

An exemplary embodiment of the present invention also discloses a method of manufacturing an organic light emitting display device, including forming first electrodes disposed on a first substrate of the organic light emitting display device respectively corresponding to red, green, and blue pixels, forming secondary transparent electrodes having different thicknesses from each other on the first electrodes corresponding to the red, green, and blue pixels by a printing process, forming organic light emitting structures on the secondary transparent electrodes, the organic light emitting structures emitting white light, and forming second electrodes on the organic light emitting structures.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a cross-sectional view of an organic light emitting display device according to an exemplary embodiment of the present invention.

FIG. 2 is a cross-sectional view of an example of an organic light emitting structure included in an organic light emitting display device of FIG. 1.

FIG. 3 is a cross-sectional view of an organic light emitting display device according to an exemplary embodiment of the present invention.

FIGS. 4A through 4C are cross-sectional views for describing a method of manufacturing an organic light emitting display device according to an exemplary embodiment of the present invention.

FIGS. 5A and 5B are cross-sectional views for describing a method of manufacturing an organic light emitting display device according to an exemplary embodiment of the present invention.

FIGS. 6A and 6B are cross-sectional views for describing a method of manufacturing an organic light emitting display device according to an exemplary embodiment of the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of elements may be exaggerated for clarity. Like or similar reference numerals in the drawings denote like or similar elements throughout.

It will be understood that when an element or layer is referred to as being “on,” “connected to”, or “coupled to” another element or layer, it can be directly on, connected or coupled to the other element or layer, or intervening elements or layers may be present. In contrast, when an element is referred to as being “directly on,” “directly connected to”, or “directly coupled to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ). As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross sectional illustrations that are schematic illustrations of illustratively idealized exemplary embodiments (and intermediate structures) of the present invention. As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

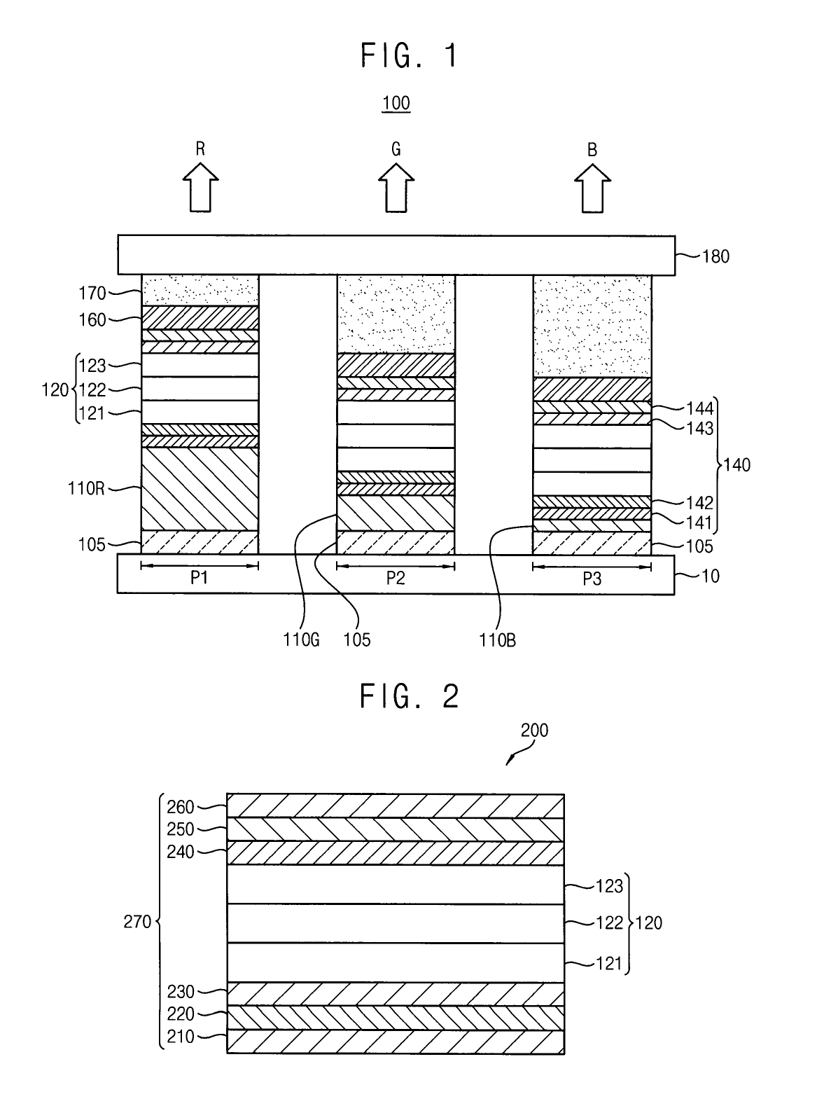

FIG. 1 is a cross-sectional view of an organic light emitting display device in accordance with an exemplary embodiment of the present invention.

Referring to FIG. 1, an organic light emitting display device 100 may include a first substrate 10, red, green, and blue pixels P1, P2, and P3, a plurality of first electrodes 105, a plurality of secondary transparent electrodes 110R, 110G, and 110B, a plurality of organic light emitting structures 140, a plurality of second electrodes 160, a plurality of filling layers 170, and a second substrate 180. Although not illustrated, the organic light emitting display device may further include thin-film transistors (TFTs) disposed on the first substrate 10, and a pixel defining layer disposed on the first substrate 10 and the first electrodes 105.

The first substrate 10 may include an insulation substrate. For example, the first substrate 10 may include a glass substrate, a quartz substrate, a transparent resin substrate, a metal oxide substrate, etc. In some exemplary embodiments, the first substrate 10 may include a flexible substrate. In some exemplary embodiments, a buffer layer including silicon oxide (SiOₓ) and/or silicon nitride (SiNₓ) may be formed on the first substrate 10 to flatten the first substrate 10 and to prevent the penetration of impurities.

Although not illustrated, a switching device may be disposed on the first substrate 10. The switching device may include a thin film transistor (TFT) or an oxide semiconductor device, etc. In the case of the TFT, each first electrode 105 may be electrically coupled to a drain electrode of the TFT. At least one insulation layer may be disposed between the switching device and each first electrode 105. The insulation layer may include an organic material. For example, the insulation layer may include a photoresist, an acryl-based polymer, a polyimide-based polymer, a polyamide-based polymer, a siloxane-based polymer, a novolak resin, an alkali-soluble resin, etc., which may be used alone or in combination. The insulation layer may be formed using an inorganic material, such as a silicon compound, a metal, a metal oxide, etc. For example, the insulation layer may include silicon oxide (SiOₓ), silicon nitride (SiNₓ), silicon oxynitride (SiOₓN_{y}), silicon oxycarbide (SiOₓC_{y}), silicon carbon nitride (SiCₓN_{y}), aluminum (Al), magnesium (Mg), zinc (Zn), hafnium (Hf), zirconium (Zr), titanium (Ti), tantalum (Ta), aluminum oxide (AlOₓ), titanium oxide (TiOₓ), magnesium oxide (MgOₓ), zinc oxide (ZrOₓ), hafnium oxide (HfOₓ), zirconium oxide (ZrOₓ), titanium oxide (TiOₓ), tantalum oxide (TaOₓ), etc., which may be used alone or in combination.

The pixels P1, P2, and P3 may be formed as a red pixel P1, a green pixel P2, and a blue pixel P3, respectively. With respect to the red, green, and blue pixels P1, P2, and P3, thicknesses of resonance layers which define distances of optical resonance may be different from each other. However, the pixels P1, P2, and P3 may not be limited to the red, green, and blue colors and instead may be pixels of any combination of other colors which realize white light when combined.

The first electrodes 105 may be formed in a pattern by a photolithography process. The first electrodes 105 may be disposed on the first substrate 10. At least one insulation layer may be further disposed between each first electrode 105 and the first substrate 10. The first electrodes 105 disposed on the first substrate corresponding to the red, green, and blue pixels P1, P2, and P3 may have the same thickness. According to the emission type of the organic light emitting display device 100, the first electrodes 105 may include a material having a reflectivity or a transmittance. For example, in a case where the organic light emitting display device is a top-emission type display device, the first electrodes 105 may include a metal, such as aluminum (Al), silver (Ag), platinum (Pt), gold (Au), chromium (Cr), tungsten (W), molybdenum (Mo), titanium (Ti), palladium (Pd), iridium (Ir), etc., or an alloy thereof. The first electrodes 105 may be formed as a double-layer or a triple-layer further including an indium tin oxide (ITO) layer or an indium zinc oxide (IZO) layer on an upper portion and/or a lower portion of the metal. In other examples, in a case where the organic light emitting display device is a bottom-emission type display device, the first electrodes 105 may include a transparent conductive oxide, such as indium tin oxide (ITO), indium zinc oxide (IZO), indium gallium oxide (IGO), zinc oxide (ZnOₓ), gallium oxide (GaOₓ), tin oxide (SnOₓ), etc.

Although not illustrated in FIG. 1, pixel defining layers may be further formed outside of (for example, around) the first electrodes 105 to define the pixels P1, P2 and P3.

The secondary transparent electrodes 110R, 110G, and 110B may respectively be formed on the first electrodes 105. The secondary transparent electrodes 110R, 110G, and 110B may have different thicknesses to emit light of different colors by using a micro-cavity effect. The secondary electrodes 110R, 110G, and 110B may be formed by a printing process. In some exemplary embodiments, the secondary transparent electrodes 110R, 110G, and 110B may be formed to have different thicknesses by an inkjet printing process. In other exemplary embodiments, the secondary transparent electrodes 110R, 110G, and 110B may be formed to have different thickness by a nozzle printing process. In still other exemplary embodiments, the secondary transparent electrodes 110R, 110G, and 110B may be formed by still another printing process. The secondary transparent electrodes 110R, 110G, and 110B may include at least one of indium tin oxide (ITO), indium zinc oxide (IZO), indium gallium oxide (IGO), zinc oxide (ZnOₓ), gallium oxide (GaOₓ) and tin oxide (SnOₓ). A thickness of the secondary transparent electrode 110R formed in the red pixel P1 may be greater than a thickness of the secondary transparent electrode 110G formed in the green pixel P2, and the thickness of the secondary transparent electrode 110G formed in the green pixel P2 may be greater than a thickness of the secondary transparent electrode 110B formed in the blue pixel P3. The secondary transparent electrodes 110R, 110G, and 110B may have relatively high work functions. The secondary transparent electrodes 110R, 110G, and 110B may be disposed between the first electrodes 105 and the organic light emitting structures 140.

The organic light emitting structures 140 may be formed on the secondary transparent electrodes 110R, 110G, and 110B, respectively. The organic light emitting structures 140 may include light emitting layers 120 which emit white light. The organic light emitting structures 140 may further include at least one of a hole injection layer 141, a hole transport layer 142, an electron transport layer 143, and an electron injection layer 144. Although not illustrated, the organic light emitting structure 140 may further include at least one of an electron blocking layer and a hole blocking layer.

The light emitting layers 120 may be of a stacking type or a tandem type. Each stacking type light emitting layer 120 may include red, green, and blue sub-light emitting layers 121, 122, and 123, and the stacking order of the sub-light emitting layers 121, 122, and 123 are not specifically limited. In the stacking type light emitting layer 120, the red, green, and blue sub-light emitting layers 121, 122, and 123 may be fluorescent light emitting layers or at least one of the sub-light emitting layers 121, 122, and 123 may be a phosphorescence layer. In the tandem type light emitting layer, the red, green, and blue sub-light emitting layers may be fluorescent light emitting layers or at least one of the sub-light emitting layers may be a phosphorescence layer. In the tandem type light emitting layer, each of the sub-light emitting layers stacked on both side of a charge generation layer (CGL) may emit white color, colors different from each other, or the same color where the colors different from each other or the same color may be a single color or multiple colors. However, the structure of the light emitting layers 120 is not limited thereto. Further, the sub-light emitting layers 121, 122, and 123 may not be limited to the red, green, and blue sub-light emitting layers 121, 122, and 123, and the sub-light emitting layers 121, 122, and 123 may be sub-light emitting layers of any combination of other colors which realize white light when combined.

The second electrodes 160 may be formed on the organic light emitting structures 140 corresponding to the first electrodes 105. The second electrodes 160 may be formed together as a common electrode. The second electrodes 160 may be a reflective electrode or a transmittance electrode, depending on the type of the first electrodes 105. In a case where the first electrodes 105 are the transmittance electrode, the second electrodes 160 may be the reflective electrode. In this case, the second electrode 160 may include Al, W, Cu, Ni, Cr, Mo, Ti, Pt, Ag, Ta, Ru, etc., or an alloy thereof. Alternatively, in a case where the first electrodes 105 are the reflective electrode, the second electrode 160 may be the transmittance electrode, and may include ITO, IZO, ZTO, GTO, ZnOₓ, InOₓ, SnOₓ, GaOₓ, etc., or a mixture thereof.

Each light emitting layer 120 may emit white light where red light, green light, and blue light respectively emitted by the sub-light emitting layers 121, 122, and 123, are combined. Resonance may occur between the first electrodes 105 and the second electrodes 160 when the white light emitted from light emitting layers 120 is reflected by the first electrodes 105. Distances between the first electrodes 105 and the second electrodes 160 may be distances of optical resonance. It is necessary to control the distances between the first electrodes 105 and the second electrodes 160 in the respective pixels P1, P2, and P3 so that the respective pixels P1, P2, and P3 emit light of different colors (e.g., red light, green light, and blue light) to the outside. To adjust the distances between the first electrodes 105 and the second electrodes 160, thicknesses of the secondary transparent electrodes 110R, 110G, and 110B may be adjusted using a printing process and, thus, the distances of optical resonance may be controlled. However, controlling the distances of optical resonance may not be limited to adjusting the thicknesses of the secondary transparent electrodes 110R, 110G, and 110B. In other exemplary embodiments, to control the distances of optical resonance, the hole injection layers 141 or the hole transport layers 142 included in the pixels P1, P2, and P3 may have different thicknesses using the printing process.

A second substrate 180 may be formed on the second electrodes 160. The second substrate 180 may include an insulation substrate. For example, the second substrate 180 may include a glass substrate, a quartz substrate, a transparent resin substrate, a metal oxide substrate, etc. The second substrate 180 may also include a flexible substrate.

The first electrodes 105 may serve as anode electrodes, and the hole injection layers 141 and the hole transport layers 142 may be disposed between the first electrodes 105 and the sub-light emitting layers 120 as illustrated in FIG. 1. However, the present invention may not be limited to the above-described structure. The first electrodes 105 may instead serve as cathode electrodes. In this case, the electron transport layers 143 and the electron injection layers 144 may be disposed between the first electrodes 105 and the sub-light emitting layers 120.

The filling layers 170 may be disposed between the second electrodes 160 and the second substrate 180 to protect the organic light emitting display device 100.

The organic light emitting display device 100 may include red, green, and blue color filters formed corresponding to the red, green and blue pixels P1, P2 and P3.

As described above, the organic light emitting display device 100 may perform full-color display by differentially controlling distances of optical resonance. The distances of optical resonance may be controlled by adjusting the thicknesses of the secondary transparent electrodes 110R, 110G, and 110B. In the organic light emitting display device 100 according to exemplary embodiments, the secondary transparent electrodes 110R, 110G, and 110B may be simultaneously formed to have different thicknesses by using the printing process. Thus, the manufacturing process may be simplified, production costs may be reduced, and defects caused by particles may be reduced. Further, by using the printing process, the process reproducibility may be improved as compared with the conventional developing and etching processes, which must be repeated.

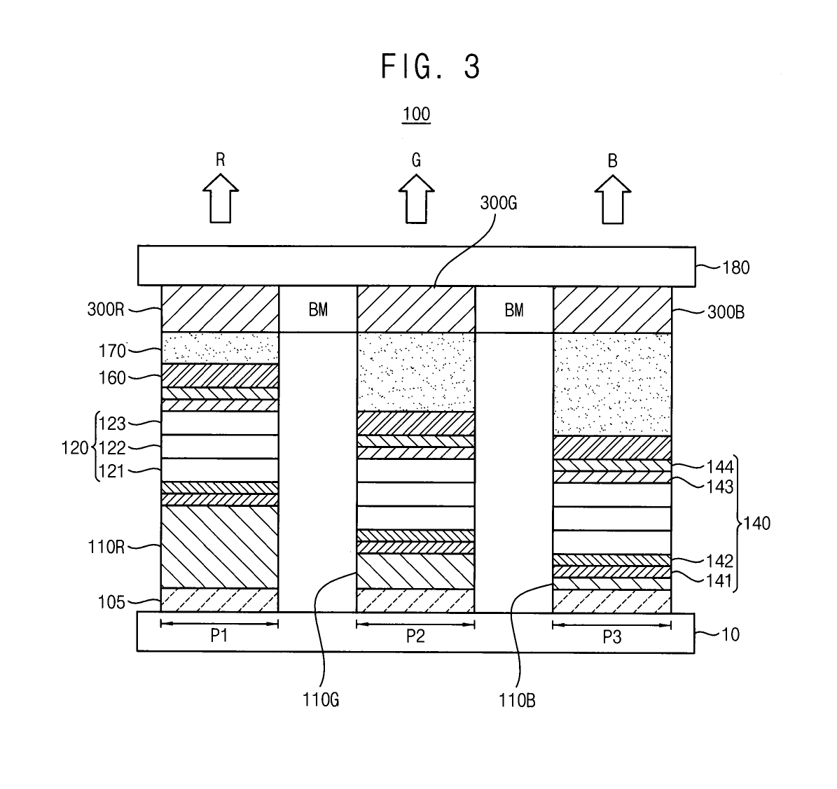

FIG. 2 is a cross-sectional view of an example of an organic light emitting structure included in the organic light emitting display device of FIG. 1.

Referring to FIG. 2, an organic light emitting structure 200 may be formed by stacking a light emitting layer 120 and at least one functional layer 270. The functional layer 270 may include at least one of a hole injection layer 210, a hole transport layer 220, an electron blocking layer 230, a hole blocking layer 240, an electron transport layer 250, and an electron injection layer 260.

The light emitting layer 120 may include sub-light emitting layers 121, 122, and 123 that emit light of different colors. The light of different colors emitted by the sub-light emitting layers 121, 122, and 123 may be optically combined for the light emitting layer 120 to emit white light. For example, the light emitting layers 120 may include the sub-light emitting layers 121, 122, and 123 that respectively emit red, green, and blue light to emit white light. However, the light of different colors emitted by the sub-light emitting layers 121, 122, and 123 may not be limited to red, green, and blue light, and any combination of other colors which realize white light when combined may be used. The sub-light emitting layers may be formed in one or two layers.

The sub-light emitting layer 121 emitting red light may be formed of a phosphorescent substance that includes carbazole biphenyl (CBP) or mCP as a host material, and includes at least one of bis(1-phenylisoquinoline)acetylacetonate iridium (PIQIr(acac)), bis(1-phenylquinoline)acetylacetonate iridium PQIr(acac)), tris(1-phenylquinoline) iridium (PQIr), and octaethylporphyrin platinum (PtPEP) as a dopant material. Alternatively, the sub-light emitting layer 121 may be formed of a fluorescent substance, such as PED:Eu(DBM)3(Phen) or Perylene.

The sub-light emitting layer 122 emitting green light may be formed of a phosphorescent substance that includes CBP or mCP as a host material and includes fac tris(2-phenylpyridine) iridium (Ir(ppy)3) as a dopant material. Alternatively, the sub-light emitting layer 122 may be formed of a fluorescent substance, such as tris(8-hydroxyquinoline)aluminum (Alq3).

The sub-light emitting layer 123 emitting blue light may be formed of a fluorescent substance including at least one of DPVBi, spiro-DPVBi, spiro-6P, distill benzene (DSB), distyrylarylene (DSA), a PFO-based polymer, a PPV-based polymer, and mixtures thereof.

Each sub-light emitting layer 121, 122, and 123 may be formed as a common layer with respect to the pixels P1, P2, and P3 by depositing the sub-light emitting layer 121, 122, and 123 in the pixels P1, P2 and P3 by using one open mask. Accordingly, the light emitting layer 120 may be easily formed without a separate patterning process for each pixel.

The hole injection layer 210 may be disposed on the secondary transparent electrode 110 as a common layer with the same thickness. The hole injection layer 210 may promote a hole injection from the first electrode 105 into the light emitting layer 120. For example, the hole injection layer 210 may include CuPc(cupper phthalocyanine), PEDOT(poly(3,4)-ethylenedioxythiophene), PANI(polyaniline), NPD(N,N-dinaphthyl-N,N′-diphenyl benzidine), etc. However, the material in the hole injection layer 210 may not be limited thereto.

The hole transport layer 220 may be located on the hole injection layer 210 or the secondary transparent electrode 110 as a common layer with the same thickness. The hole transport layer 220 may improve a hole movement from the hole injection layer 210. For example, the hole transport layer 220 may include NPD(N,N-dinaphthyl-N,N′-diphenylbenzidine), TPD(N,N′-bis-(3-methylphenyl)-N,N′-bis-(phenyl)-benzidine), s-TAD, MTDATA(4,4′,4″-Tris(N-3-methylphenyl-N-phenyl-amino)-triphenylamine), etc. However, the material in the hole transport layer 220 may not be limited thereto.

The hole blocking layer 240 may be located on the light emitting layer 120 as a common layer with the same thickness. The hole blocking layer 240 may be formed of biphenoxy-bi(8-quinolitolato)aluminum (Balq).

The electron transport layer 250 may be located on the hole blocking layer 240 or the light emitting layer 120 as a common layer with the same thickness. The electron transport layer 250 may be formed of a polycyclic hydrocarbon based derivative, a heterocyclic compound, or tris(8-hydroxyquinolinato)aluminum (Alq3).

The electron injection layer 260 may be located on the electron transport layer 250 as a common layer having the same thickness throughout. The electron injection layer 260 may be formed of LiF, Liq, NaF, or Naq.

The light emitting layer 120 and the functional layer 270 included in the organic light emitting structure 200 may be formed in each pixel P1, P2, and P3 as a common layer by using one open mask. Thus, the organic light emitting structure 200 may be easily formed without the need for a separate patterning process for each pixel.

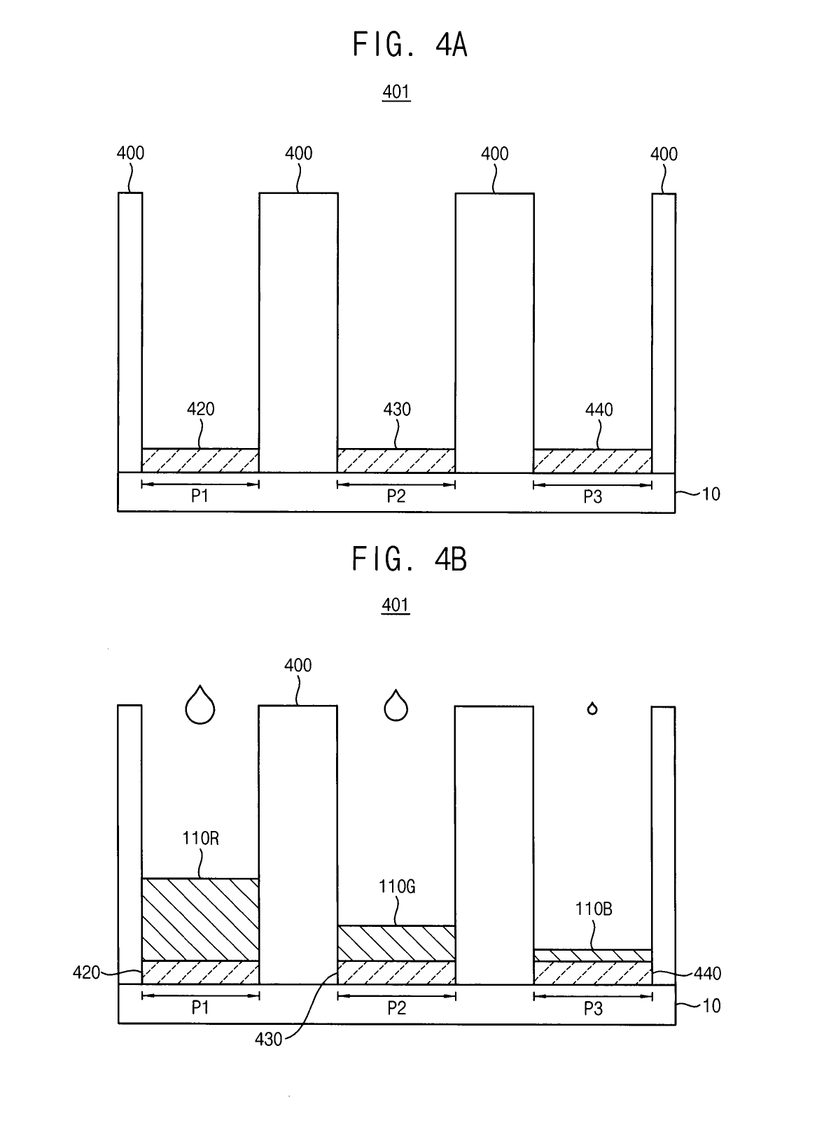

FIG. 3 is a cross-sectional view of an organic light emitting display device according to another exemplary embodiment of the present invention.

Referring to FIGS. 1 and 3, the organic light emitting display device 100 may include first and second electrodes 105 and 160. The organic light emitting display device 100 may further include secondary transparent electrodes 110R, 110G, and 110B and organic light emitting structures 140 disposed between the first electrodes 105 and the second electrodes 160. The organic light emitting display device 100 may further include filling layers 170, and red, green, and blue color filters 300R, 330G, and 300B on the second electrodes 160. The light emitting layer 120 including sub-light emitting layers 121, 122, and 123 may emit white light in which the light of different colors emitted by the sub-light emitting layers 121, 122, and 123 are combined.

The secondary transparent electrodes 110R, 110G, and 110B may be formed to have different thicknesses using a simple process, such as a printing process. Accordingly, the distances of optical resonance designed to each have a different length according to each pixel P1, P2, and P3 strengthens emission of light that has a wavelength that is close to a wavelength corresponding to a resonant wavelength designed for each pixel P1, P2, and P3, and suppresses emission of light that has a wavelength that is close to other wavelengths. Thus, a red light R, a green light G, and a blue light B are respectively strengthened and emitted from the pixel P1, P2 and P3 to the outside.

The organic light emitting display device 100 may further include red, green, and blue color filters 300R, 300G, and 300B corresponding to the red, green, and blue pixels P1, P2, and P3, and a black matrix (BM) may be disposed between the color filters 300R, 300G, and 300B.

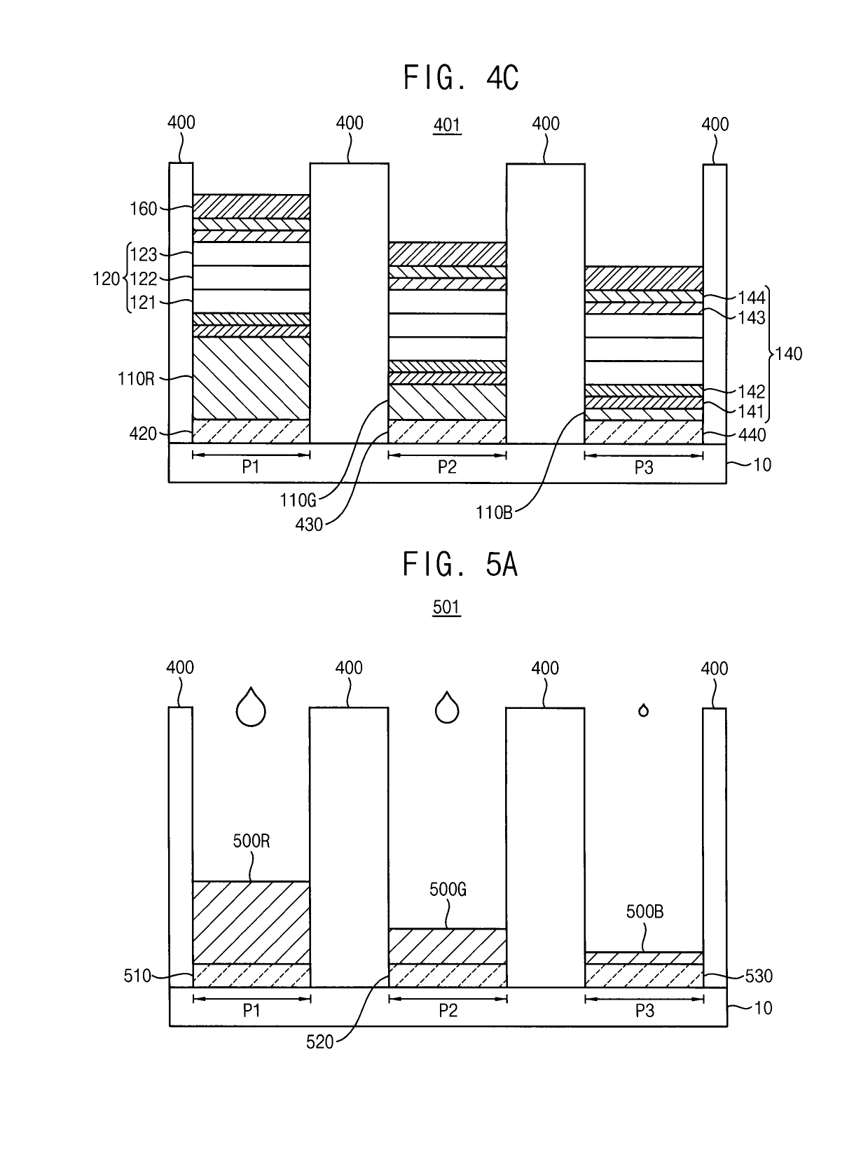

FIGS. 4A through 4C are cross-sectional views for describing a method of manufacturing an organic light emitting display device according to an exemplary embodiment of the present invention.

Referring to FIG. 4A, first electrodes 420, 430, and 440 may be formed on a first substrate 10. The first substrate 10 may include an insulation substrate or a flexible substrate. Pixel defining layer 400 may be disposed on the first substrate 10 to partially expose the first electrodes 420, 430, and 440.

The pixel defining layer 400 may include an organic material. For example, the pixel defining layer 400 may include benzocylcobutene (BCB), a photoresist, a phenol-based resin, a polyacryl-based resin, a polyimid-based resin, an acryl-based resin, etc. The pixel defining layer 400 may include an inorganic material. For example, the pixel defining layer 400 may include silicon oxide (SiOₓ), silicon nitride (SiNₓ), silicon oxynitride (SiOₓN_{y}), silicon oxycarbide (SiOₓC_{y}), etc.

The pixel defining layer 400 may define a red pixel P1, a green pixel P2, a blue pixel P3, and a non-display region of the organic light emitting display device 401. The pixel defining layer 400 may have an opening which exposes portions of the first electrodes 420, 430, and 440. The opening of the pixel defining layer 400 may substantially define the red, green, and blue pixels P1, P2, and P3 and the non-display region of the organic light emitting display device 401. For example, a portion of the first substrate 10 having the opening of the pixel defining layer 400 may be the display region, while another portion of the first substrate 10 substantially surrounding the opening of the pixel defining layer 400 may be the non-display region.

Although it is not illustrated, a switching device may be disposed on the first substrate 10. The switching device may include a thin film transistor (TFT), an oxide semiconductor device, etc. When the switching device includes a TFT, each first electrode 420, 430, and 440 may be electrically coupled to a drain electrode of the TFT. At least one insulation layer may be disposed between the switching device and each first electrode 420, 430, and 440. The insulation layer may include an organic material or an inorganic material.

Referring to FIG. 4B, secondary transparent electrodes 110R, 110G, and 110B may be formed on the first electrodes 420, 430, and 440, respectively. The secondary transparent electrodes 110R, 110G, and 110B may have different thicknesses to emit the light of different colors by using a micro-cavity effect. A micro-cavity effect may be caused by resonance of white light between the first electrodes 420, 430, and 440 and the second electrodes 160. Accordingly, distances of optical resonance designed to each have a different length according to each pixel P1, P2, and P3 strengthens emission of light that has a wavelength that is close to a wavelength corresponding to a resonant wavelength designed for each pixel P1, P2, and P3, and suppresses emission of light that has a wavelength that is close to other wavelengths. In order to increase luminance of the organic light emitting display device 401 by maximizing the micro-cavity effect, a thickness of the secondary transparent electrode 110R formed in the red pixel P1 may be greater than a thickness of the secondary transparent electrode 110G formed in the green pixel P2, and the thickness of the secondary transparent electrode 110G formed in the green pixel P2 may be greater than a thickness of the secondary transparent electrode 110B formed in the blue pixel P3.

The secondary electrodes 110R, 110G, and 110B may be formed by a printing process. The secondary transparent electrodes 110R, 110G, and 110B may be formed to have different thicknesses by an inkjet printing process. In other exemplary embodiments, the secondary transparent electrodes 110R, 110G and 110B may be formed to have different thickness by a nozzle printing process. In still other exemplary embodiments, the secondary transparent electrodes 110R, 110G, and 110B may be formed by another printing process. For example, the secondary transparent electrodes 110R, 110G, and 110B may be formed to have different thicknesses by an offset printing process, a gravure offset printing process, a gravure reverse offset printing process, a T-jet process, etc.

Thus, the manufacturing process may be simplified, and the facility and production costs may be reduced. Further, because of developing and etching process is not necessary, chemical deterioration of and particle generation in the substrate or materials may be prevented.

The secondary transparent electrodes 110R, 110G, and 110B may include at least one of indium tin oxide (ITO), indium zinc oxide (IZO), indium gallium oxide (IGO), zinc oxide (ZnOx), gallium oxide (GaOx) and tin oxide (SnOx).

Referring to FIG. 4C, organic light emitting structures 140 may be respectively formed on the secondary transparent electrodes 110R, 110G, and 110B. The organic light emitting structures 140 may include light emitting layers 120 which emit white light. The organic light emitting structures 140 may further include at least one of a hole injection layer 141, a hole transport layer 142, an electron transport layer 143, and an electron injection layer u) 144. Although not illustrated, the organic light emitting structure 140 may further include at least one of an electron blocking layer and a hole blocking layer.

Each organic light emitting structure 120 may include a plurality of stacked sub-light emitting layers 121, 122, and 123 that emit light of different colors, and the light of different colors emitted by the sub-light emitting layers 121, 122, and 123 may be combined to emit white light. For example, each light emitting layer 120 may include red, green, and blue sub-light emitting layers 121, 122 and 123, and the stacking order of the sub-light emitting layers 121, 122, and 123 are not specifically limited. However, the structure of the light emitting layers 120 is not limited thereto. The sub-light emitting layers 121, 122, and 123 may not be limited to the red, green, and blue sub-light emitting layers 121, 122, and 123, and the sub-light emitting layers 121, 122, and 123 may be sub-light emitting layers of any combination of other colors which realize white light when combined. Moreover, the sub-light emitting layers may be formed in one or two layers.

A functional layer may be formed by stacking at least one of the hole injection layer 141, the hole transport layer 142, the electron transport layer 143, and the electron injection layer 144 in a single or composite structure.

As illustrated in FIG. 4C, the light emitting layer 120 and the functional layers 141, 142, 143 and 144 included the organic light emitting structure 140 may be formed in each pixel P1, P2 and P3 as a common layer by using one open mask. Thus, the organic light emitting structure 140 may be easily formed without a separate patterning process for each pixel.

Since the organic light emitting structures 140 and the second electrodes 160 are described above referred to FIG. 1 and FIG. 2, duplicate descriptions will not be repeated.

In exemplary embodiments, red, green, and blue color filters may be formed in correspondence to the red, green, and blue pixels P1, P2 and P3, respectively. A second substrate performing a package may be formed on the second electrodes 160, and filling layers may be formed between the second electrode 160 and the second substrate to protect the organic light emitting display device 401.

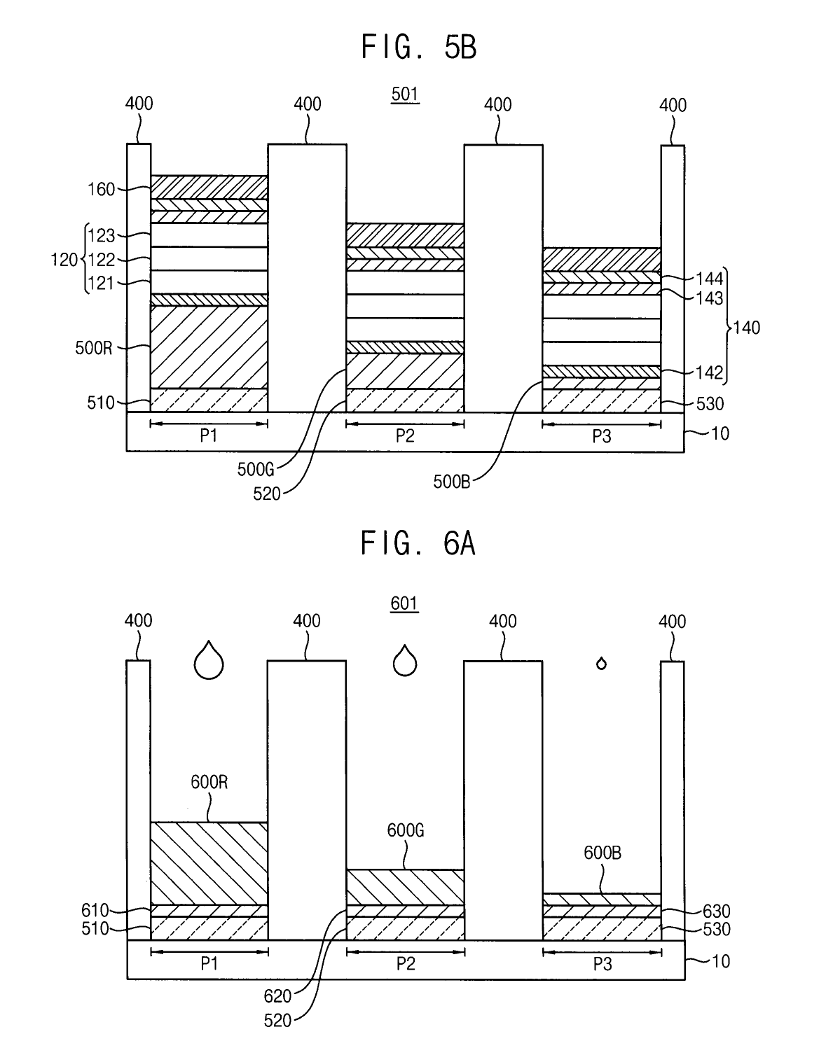

FIGS. 5A and 5B are cross-sectional views for describing a method of manufacturing an organic light emitting display device according to an exemplary embodiment of the present invention.

Referring to FIG. 5A, first electrodes 510, 520, and 530 may be formed on a first substrate 10 to have the same thickness. The pixel defining layer 400 defining a red pixel P1, a green pixel P2, a blue pixel P3, and a non-display region may be formed on the first substrate 10 and the first electrodes 510, 520 and 530. When the organic light emitting display device 501 is a top-emission type display device, the first electrodes 510, 520, and 530 may include a metal, such as aluminum (Al), silver (Ag), platinum (Pt), gold (Au), chromium (Cr), tungsten (W), molybdenum (Mo), titanium (Ti), palladium (Pd), iridium (Ir), etc., or an alloy thereof. The first electrodes 510, 520, and 530 may be formed as a double-layer or a triple-layer further including an indium tin oxide (ITO) layer or an indium zinc oxide (IZO) layer on an upper portion and/or a lower portion of the metal.

Each of the hole injection layers 500R, 500G, and 500B may be formed on the first electrodes 510, 520, and 530, respectively. The hole injection layers 500R, 500G, and 500B may have different thicknesses to emit light of different colors by using a micro-cavity effect. The hole injection layers 500R, 500G, and 500B may be formed by a printing process.

Referring to FIG. 5B, the hole transport layer 142, the light emitting layer 120, the electron transport layer 143, and the electron injection layer 144 may be sequentially formed in each pixel P1, P2, and P3 as a common layer by using one open mask. Further, the second electrode 160 may be formed on organic light emitting structures 140. Although not illustrated, the method of manufacturing the organic light emitting display device 501 may include forming filling layers, a second substrate, and color filters, etc.

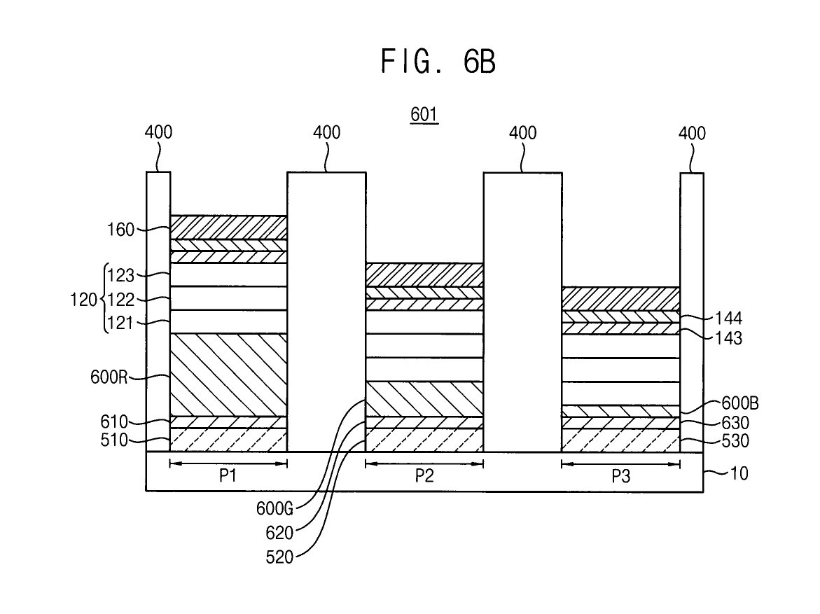

FIGS. 6A and 6B are cross-sectional views for describing a method of manufacturing an organic light emitting display device according to an exemplary embodiment of the present invention.

Referring to FIG. 6A, first electrodes 510, 520, and 530, pixel defining layer 400, and hole injection layers 610, 620, and 630 may be sequentially formed on a first substrate 10 as a common layer by using one open mask.

Hole transport layers 600R, 600G, and 600B may have different thicknesses to emit light of different colors by using micro-cavity effect. The hole transport layers 600R, 600G, and 600B may be formed by a printing process.

Referring to FIG. 6B, the light emitting layer 120, the electron transport layer 143, and the electron injection layer 144 may be sequentially formed in each pixel P1, P2, and P3 as a common layer by using one open mask. Further, the second electrode 160 may be formed on organic light emitting structures 140. Although not illustrated, a method of manufacturing the organic light emitting display device may include forming filling layers, a second substrate, and color filters, etc.

The present invention may be applied to any organic light emitting display device using micro-cavity effect to realize display and manufacturing process the same. For example, the present invention may be applied to various electronic and electric apparatuses, such as a mobile phone, a smart phone, a laptop computer, a tablet computer, a personal digital assistants (PDA), a portable multimedia player (PMP), a digital camera, a music player, a portable game console, a navigation device, etc.

Therefore, an organic light emitting display device according to the present invention may reduce facility and production costs, and may have a reduced number of undesirable particles by utilizing a printing process which results in a different distance of optical resonance for each pixel (e.g., different thicknesses of secondary transparent electrodes, hole injection layers, or hole transport layers). By using such a printing process, process reproducibility may be improved as compared with the conventional repeated developing and etching processes.

In addition, a method of manufacturing the organic light emitting display device according to the present invention may simplify the manufacturing process by utilizing a printing process to have different distances of optical resonance for each pixel (e.g., different thicknesses of secondary transparent electrodes, hole injection layers, or hole transport layers). Thus, because the manufacturing process may be simplified, facility and production costs may be reduced. Further, because the developing and etching process is not necessary, chemical deterioration and particle generation in the substrate or materials may be reduced or prevented.

The foregoing is illustrative of exemplary embodiments, and is not to be construed as limiting thereof. It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents. In the claims, means-plus-function clauses are intended to cover the structures described herein as performing the recited function and not only structural equivalents but also equivalent structures. Therefore, it is to be understood that the foregoing is illustrative of exemplary embodiments and is not to be construed as limited to the specific embodiments disclosed, and that modifications to the disclosed exemplary embodiments, as well as other exemplary embodiments, are intended to be included within the scope of the appended claims. The present invention is defined by the following claims, with equivalents of the claims to be included therein.

What is claimed is:

1. An organic light emitting display device comprising a first substrate on which red, green, and blue pixels are formed, the red, green, and blue pixels comprising:
a plurality of first electrodes disposed on the substrate and respectively corresponding to the red, green, and blue pixels;
a plurality of organic light emitting structures disposed on the first electrodes corresponding to the red, green, and blue pixels, respectively, the organic light emitting structures configured to emit white light;
a plurality of second electrodes respectively disposed on the organic light emitting structures; and
a plurality of secondary printed, transparent electrodes disposed between the first electrodes and the organic light emitting structures, the secondary printed, transparent electrodes having different thicknesses from each other such that red light, green light, and blue light are respectively emitted by the red, green, and blue pixels when the white light causes resonance to occur between the first electrodes and the second electrodes.

2. The organic light emitting display device of claim 1, wherein each of the plurality of first electrodes and each of the plurality of the second electrodes comprises a material having a reflectivity or a material having a transmittance.

3. The organic light emitting display device of claim 1, wherein each of the plurality of secondary printed, transparent electrodes comprises at least one of indium tin oxide (ITO), indium zinc oxide (IZO), indium gallium oxide (IGO), zinc oxide (ZnOx), gallium oxide (GaOx), and tin oxide (SnOx).

4. The organic light emitting display device of claim 1, wherein the secondary printed, transparent electrodes are inkjet-printed electrodes.

5. The organic light emitting display device of claim 1, wherein the secondary printed, transparent electrodes are nozzle-printed electrodes.

6. The organic light emitting display device of claim 1, wherein each of the plurality of organic light emitting structures comprises a plurality of sub-light emitting layers configured to emit light of different colors which are combined to emit white light.

7. The organic light emitting display device of claim 1, wherein each of the plurality of organic light emitting structures comprises at least one of a hole injection layer, a hole transport layer, an electron blocking layer, a hole blocking layer, an electron transport layer, and an electron injection layer.

8. The organic light emitting display device of claim 1, further comprising:
a second substrate comprising an insulation substrate disposed on the second electrodes.

9. The organic light emitting display device of claim 1, further comprising:
red, green, and blue color filters disposed on the substrate and respectively corresponding to the red, green, and blue pixels.

10. A method of manufacturing an organic light emitting display device, comprising:
forming a plurality of first electrodes on a first substrate respectively corresponding to red, green, and blue pixels;
forming a plurality of secondary transparent electrodes on the first electrodes corresponding to the red, green and blue pixels by a printing process, the secondary transparent electrodes having different thicknesses from each other;
forming a plurality of organic light emitting structures on the secondary transparent electrodes, the organic light emitting structures configured to emit white light; and
forming a plurality of second electrodes on the organic light emitting structures.

11. The method of claim 10, further comprising:
forming an underlying structure comprising a switching device and an insulation layer disposed between the first substrate and the first electrodes.

12. The method of claim 10, further comprising:
forming a pixel defining layer defining the red, green, and blue pixels on the first substrate.

13. The method of claim 10, wherein the printing process comprises an inkjet printing process.

14. The method of claim 10, wherein the printing process comprises a nozzle printing process.

15. The method of claim 10, wherein each organic light emitting structure comprises a plurality of stacked sub-light emitting layers configured to emit light of different colors, and the light of different colors emitted by the sub-light emitting layers are combined to emit the white light.

16. The method of claim 10, further comprising:
forming red, green and blue color filters on the substrate, the red, green, and blue color filters respectively corresponding to the red, green and blue pixels.

17. The method of claim 10, further comprising:
forming a second substrate on the second electrodes, the second substrate comprising an insulation substrate.

18. An organic light emitting display device comprising a first substrate on which red, green, and blue pixels are formed, the red, green, and blue pixels comprising:
a plurality of first electrodes disposed on the substrate and respectively corresponding to the red, green, and blue pixels;
a plurality of organic light emitting structures disposed on the first electrodes corresponding to the red, green and blue pixels, respectively, the organic light emitting structures configured to emit white light;
a plurality of second electrodes respectively disposed on the organic light emitting structures; and
a plurality of secondary transparent electrodes disposed between the first electrodes and the organic light emitting structures, the secondary transparent electrodes having different thicknesses from each other such that red light, green light, and blue light are respectively emitted by the red, green, and blue pixels when the white light causes resonance to occur between the first electrodes and the second electrodes.

19. The organic light emitting display device of claim 18, wherein secondary transparent electrodes are formed by an inkjet printing process.

20. The organic light emitting display device of claim 18, wherein the secondary transparent electrodes are formed by a nozzle printing process.
